(19) United States
(12) Patent Application Publication
(10) Pub. No.: US 2026/0055295 A1
(43) Pub. Date: Feb. 26, 2026

(54) COPOLYMER, PIEZOELECTRIC MATERIAL, PIEZOELECTRIC FILM, AND PIEZOELECTRIC ELEMENT

(71) Applicant: TDK CORPORATION, Tokyo (JP)

(72) Inventor: Junichi HOSHINO, Tokyo (JP)

(73) Assignee: TDK CORPORATION, Tokyo (JP)

(21) Appl. No.: 19/103,767

(22) PCT Filed: Jul. 5, 2023
(86) PCT No.: PCT/JP2023/024946

§ 371 Date: Feb. 13, 2025

(30) Foreign Application Priority Data
Aug. 24, 2022 (JP) 2022-133097

(51) Int. Cl. C09D 139/04; H10N 30/00; H10N 30/857; H10N 30/87

(52) U.S. Cl. CPC C09D 139/04; H10N 30/704; H10N 30/857; H10N 30/87

(57) ABSTRACT

This copolymer has a structural unit including a triazole skeleton that is any one or more of (1-1) to (1-3) (R¹ to R⁶ are each any one selected from the group made of a hydrogen atom, a methyl group, a trifluoromethyl group, a nitrile group, a fluorine atom, a methoxy group, an ethyl group, an ethoxy group, a methoxymethyl group, a propyl group, an isopropyl group, a cyclopropyl group, a butyl group, an isobutyl group, a (trimethyl)methyl group, a (trimethyl) silyl group, a pentyl group, an isopentyl group, a t-pentyl group, a neopentyl group, a cyclopentyl group, a hexyl group, a cyclohexyl group, a phenyl group, a tolyl group, a benzyl group, and a phenoxymethyl group, or R¹ to R⁶ each form a benzotriazole skeleton together with a triazole ring) and a structural unit represented by Formula (2).

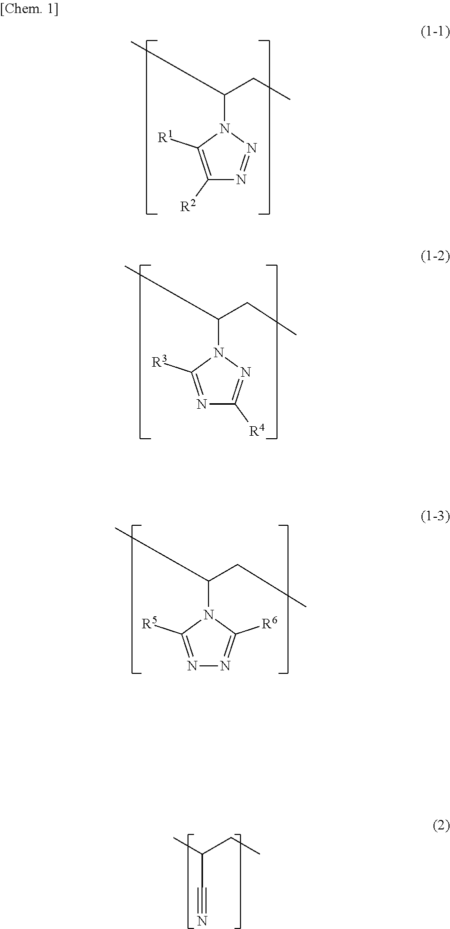

### TECHNICAL FIELD

The present invention relates to a copolymer, a piezoelectric material, a piezoelectric film, and a piezoelectric element.

Priority is claimed on Japanese Patent Application No. 2022-133097, filed Aug. 24, 2022, the content of which is incorporated herein by reference.

### BACKGROUND ART

In recent years, as a piezoelectric material that forms piezoelectric bodies in piezoelectric elements, PZT (PbZrO₃—PbTiO₃-based solid solution), which is a ceramic material, has been in frequent use. However, PZT is a ceramic containing lead and thus has a disadvantage of being brittle. Therefore, there is a demand for a highly flexible material having a low environmental impact as a piezoelectric material.

As a piezoelectric material that meets such a requirement, the use of a polymer piezoelectric material is considered. The polymer piezoelectric material is a ferroelectric polymer, such as polyvinylidene fluoride (PVDF) or a vinylidene fluoride/trifluoroethylene copolymer (P(VDF/TrFE)). However, these ferroelectric polymers have insufficient heat resistance. Therefore, when piezoelectric bodies made of a conventional ferroelectric polymer reach high temperatures, piezoelectric properties are lost, and physical properties, such as the elastic modulus, deteriorate. Therefore, piezoelectric elements having a piezoelectric body made of a conventional ferroelectric polymer can be used in a narrow temperature range.

In addition, as a piezoelectric material, there is an amorphous polymer piezoelectric material that acquires piezoelectricity by being cooled and polarized at temperatures near the glass transition temperature. Amorphous polymers lose piezoelectric properties when reaching temperatures near the glass transition temperature. Therefore, there is a demand for an amorphous polymer piezoelectric material having a high glass transition temperature and favorable heat resistance.

As an amorphous polymer piezoelectric material having a high glass transition temperature, a vinylidene cyanide/vinyl acetate copolymer is an exemplary example (for example, refer to Patent Document 1). However, for the vinylidene cyanide/vinyl acetate copolymer, there is a need to use vinylidene cyanide that is hard to handle as a raw material monomer.

In addition, as a raw material monomer for polymer piezoelectric materials, the use of acrylonitrile, which is easy to handle, is considered instead of using vinylidene cyanide. However, polymers for which acrylonitrile is used as a raw material monomer have low glass transition temperatures. In addition, polymers for which acrylonitrile is used as a raw material monomer also have poor piezoelectric properties (for example, refer to Patent Document 1 and Non-Patent Document 2).

### CITATION LIST

### Patent Document

Patent Document 1: PCT International Publication No. WO 1991/013922

### Non Patent Document

Non-Patent Document 1: H. Ueda, S. Carr, Piezoelectricity in Polyacrylonitrile. Polym J 16, 661 to 667 (1984).
Non Patent Document 2: H. von Berlepsch, W. Kunstler, Piezoelectricity in acrylonitrile/methylacrylate copolymer. Polymer Bulletin 19, 305 to 309 (1988).

### SUMMARY OF INVENTION

### Technical Problem

Conventionally, there has been a demand for a polymer piezoelectric material from which a piezoelectric film having high heat resistance and high piezoelectric properties can be obtained.

The present invention has been made in consideration of the above-described circumstance, and an object of the present invention is to provide a copolymer that can be used as a piezoelectric material from which a piezoelectric film having high heat resistance and high piezoelectric properties can be obtained.

In addition, another object of the present invention is to provide a piezoelectric material containing the copolymer of the present invention from which a piezoelectric film having high heat resistance and high piezoelectric properties can be obtained.

In addition, still another object of the present invention is to provide a piezoelectric film containing the piezoelectric material of the present invention and having high heat resistance and high piezoelectric properties and a piezoelectric element having the piezoelectric film of the present invention and having high heat resistance and high piezoelectric properties.

### Solution to Problem

In order to achieve the aforementioned objects, the following means is provided. A copolymer according to one aspect of the present invention is a copolymer having a structural unit including a triazole skeleton and a structural unit represented by following Formula (2), in which the structural unit including a triazole skeleton is any one or more of following General Formula (1-1) to General Formula (1-3).

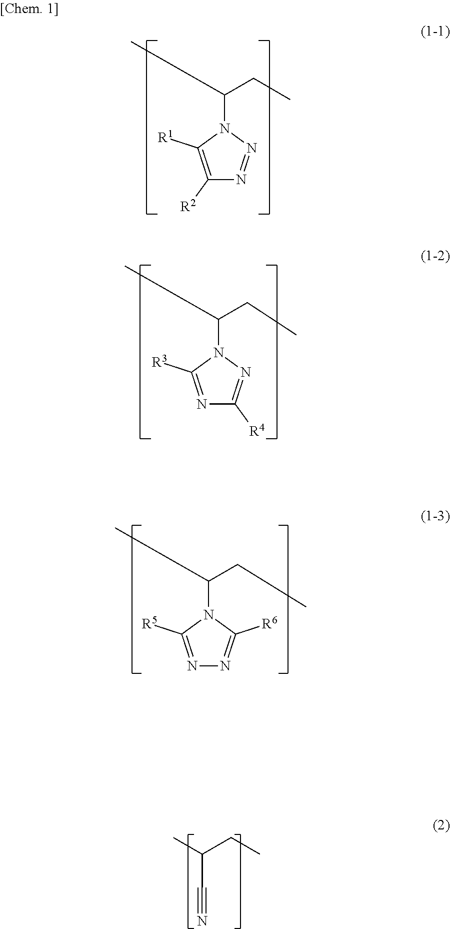

(In General Formula (1-1) to General Formula (1-3), R¹ to R⁶ are each any one selected from the group consisting of a hydrogen atom, a methyl group, a trifluoromethyl group, a nitrile group, a fluorine atom, a methoxy group, an ethyl group, an ethoxy group, a methoxymethyl group, a propyl group, an isopropyl group, a cyclopropyl group, a butyl group, an isobutyl group, a (trimethyl)methyl group, a (trimethyl) silyl group, a pentyl group, an isopentyl group, a t-pentyl group, a neopentyl group, a cyclopentyl group, a hexyl group, a cyclohexyl group, a phenyl group, a tolyl group, a benzyl group, and a phenoxymethyl group, or R¹ to R⁶ each form a benzotriazole skeleton together with a triazole ring.)

### Advantageous Effects of Invention

The copolymer of the present invention has the structural unit including a triazole skeleton that is any one or more of the General Formula (1-1) to the General Formula (1-3) and the structural unit represented by the Formula (2). Therefore, the copolymer of the present invention can be used as a piezoelectric material from which a piezoelectric film having high heat resistance and high piezoelectric properties can be obtained.

### BRIEF DESCRIPTION OF DRAWINGS

FIG. 1 A 1H-NMR measurement chart of a polymer of Example 3.

FIG. 2 An enlarged view obtained by enlarging a part of FIG. 1.

FIG. 3 A 1H-NMR measurement chart of a polymer of Example 8.

FIG. 4 An enlarged view obtained by enlarging a part of FIG. 3.

### DESCRIPTION OF EMBODIMENTS

In order to achieve the above-described objects, the present inventors paid attention to the heat resistance of a polymer for which acrylonitrile is used as a raw material monomer and repeated intensive studies.

As a result, it was found that a copolymer having a specific structural unit including a triazole skeleton and a structural unit derived from acrylonitrile is preferable.

A compound having a vinyl group bonded to a nitrogen atom in a triazole skeleton has a high affinity to acrylonitrile. Therefore, the compound having a vinyl group bonded to a nitrogen atom in a triazole skeleton is capable of forming a copolymer with acrylonitrile. In addition, the compound having a vinyl group bonded to a nitrogen atom in a triazole skeleton is a highly polar five-membered aromatic compound and thus forms a copolymer having favorable heat resistance compared with polyacrylonitriles by being copolymerized with acrylonitrile.

Specifically, the dipole moment of a compound including a triazole skeleton is approximately 4.0 to 5.0 debyes, and the dipole moment of acrylonitrile is approximately 3.8 debyes. That is, the structural unit including a triazole skeleton is more polar than the structural unit derived from acrylonitrile. As a result, in the copolymer having the structural unit including a triazole skeleton and the structural unit derived from acrylonitrile, an ordered structure enabling a nitrile group, which is a polar group derived from acrylonitrile, to be formed is disturbed due to the highly polar structural unit including a triazole skeleton and nitrile groups are less likely to be oriented such that the polarities cancel out each other. Furthermore, this copolymer has favorable heat resistance derived from a five-membered aromatic compound in the structural unit including a triazole skeleton. It is assumed that this makes the copolymer having the structural unit including a triazole skeleton and the structural unit derived from acrylonitrile become a piezoelectric material from which a piezoelectric film having favorable heat resistance and favorable piezoelectric properties can be obtained.

In addition, the compound having a vinyl group bonded to a nitrogen atom in a triazole skeleton is, for example, a compound including a six-membered ring skeleton that has a small volume and a high polarity compared with a triazine skeleton and thus makes it possible to include a large amount of the highly polar structural unit including a triazole skeleton when made into a piezoelectric material.

The use of a compound having a skeleton similar to the triazole skeleton instead of the compound having a triazole skeleton can be considered. Specifically, the use of, for example, a compound including an imidazole skeleton that is a compound having a five-membered ring containing nitrogen atoms like triazole, in which the five-membered ring contains two nitrogen atoms, a compound including a skeleton in which a five-membered ring contains four nitrogen atoms, a compound including a six-membered ring skeleton containing nitrogen, or the like can be considered. However, a copolymer having a structural unit including an imidazole skeleton and a structural unit derived from acrylonitrile has a disadvantage of being easily decomposed since compounds including an imidazole skeleton are highly basic. In addition, the compound including a skeleton in which a five-membered ring contains four nitrogen atoms and the compound including a six-membered ring skeleton containing nitrogen are poorly polar. Therefore, piezoelectric films containing a copolymer having a structural unit derived from this compound instead of the structural unit including a triazole skeleton are not capable of obtaining favorable heat resistance and favorable piezoelectric properties.

Furthermore, the present inventors produced a copolymer having a specific structural unit including a triazole skeleton and a structural unit derived from acrylonitrile, confirmed that the heat resistance thereof was favorable and the piezoelectric properties of a piezoelectric film for which this copolymer was used as a piezoelectric material were favorable, and obtained an idea of the present invention.

The present invention includes the following aspects.

[1] A copolymer having a structural unit including a triazole skeleton and a structural unit represented by Formula (2), in which the structural unit including a triazole skeleton is any one or more of following General Formula (1-1) to General Formula (1-3).

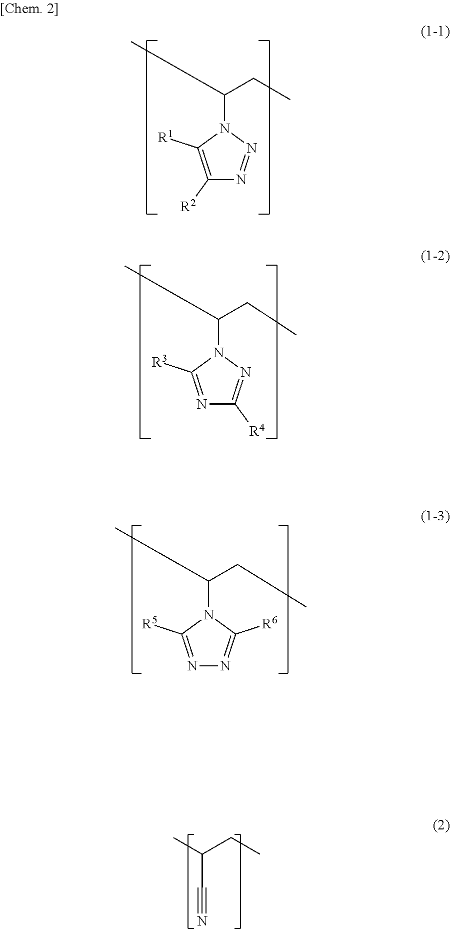

(In General Formula (1-1) to General Formula (1-3), R¹ to R⁶ are each any one selected from the group consisting of a hydrogen atom, a methyl group, a trifluoromethyl group, a nitrile group, a fluorine atom, a methoxy group, an ethyl group, an ethoxy group, a methoxymethyl group, a propyl group, an isopropyl group, a cyclopropyl group, a butyl group, an isobutyl group, a (trimethyl)methyl group, a (trimethyl) silyl group, a pentyl group, an isopentyl group, a t-pentyl group, a neopentyl group, a cyclopentyl group, a hexyl group, a cyclohexyl group, a phenyl group, a tolyl group, a benzyl group, and a phenoxymethyl group, or R¹ to R⁶ each form a benzotriazole skeleton together with a triazole ring.)

[2] The copolymer according to [1], in which, in General Formula (1-1) to General Formula (1-3), R¹ to R⁶ are hydrogen atoms.

[3] The copolymer according to [1] or [2], in which an amount of the structural unit represented by Formula (2) is 20 to 80 mol %.

[4] A piezoelectric material containing the copolymer according to [1] to [3].

[5] A piezoelectric film containing the copolymer according to [1] to [3].

[6] A piezoelectric element having the piezoelectric film according to [5] and an electrode disposed on each of a first surface and a second surface of the piezoelectric film.

Hereinafter, the copolymer, piezoelectric material, piezoelectric film, and piezoelectric element of the present invention will be described in detail.

### [Copolymer]

A copolymer (polymer) of the present embodiment has a structural unit including a triazole skeleton and a structural unit represented by Formula (2).

The structural unit including a triazole skeleton is a structural unit represented by any one or more of Formula (1-1) to Formula (1-3). Therefore, the structural unit including a triazole skeleton in the copolymer may be one structural unit selected from Formula (1-1) to Formula (1-3) or may be two or three structural units selected from Formula (1-1) to Formula (1-3). The structural unit including a triazole skeleton in the copolymer is preferably one structural unit selected from Formula (1-1) to Formula (1-3) since the number of the kinds of raw materials used is small, and the structural unit can be easily produced. In addition, the structural unit including a triazole skeleton is a piezoelectric material from which a piezoelectric film having favorable heat resistance and favorable piezoelectric properties can be obtained and is thus preferably composed of any one of Formula (1-1) and Formula (1-3) alone and more preferably composed of Formula (1-3) alone.

In the structural unit including a triazole skeleton in the copolymer of the present embodiment, R¹ to R⁶ are each any one selected from the group consisting of a hydrogen atom, a methyl group, a trifluoromethyl group, a nitrile group, a fluorine atom, a methoxy group, an ethyl group, an ethoxy group, a methoxymethyl group, a propyl group, an isopropyl group, a cyclopropyl group, a butyl group, an isobutyl group, a (trimethyl)methyl group, a (trimethyl) silyl group, a pentyl group, an isopentyl group, a t-pentyl group, a neopentyl group, a cyclopentyl group, a hexyl group, a cyclohexyl group, a phenyl group, a tolyl group, a benzyl group, and a phenoxymethyl group. The copolymer of the present embodiment can be easily produced since R¹ to R⁶ in the structural unit including a triazole skeleton are the above-described groups. In addition, the copolymer of the present embodiment can be used as a material for piezoelectric films having favorable heat resistance and favorable piezoelectric properties since R¹ to R⁶ in the structural unit including a triazole skeleton are the above-described groups. R¹ to R⁶ in the structural unit including a triazole skeleton are preferably groups having a small volume. This is because it is possible to secure the volume proportion of a triazole ring contributing to a high polarity in the structural unit including a triazole skeleton. Specifically, R¹ to R⁶ are preferably hydrogen atoms or nitrile groups and more preferably hydrogen atoms.

In the structural unit including a triazole skeleton, R¹ to R⁶ may each form a benzotriazole skeleton together with a triazole ring. Even in a case where the R¹ to R⁶ in the structural unit including a triazole skeleton in the copolymer of the present embodiment form a benzotriazole skeleton together with a triazole ring, the copolymer can be easily produced and can be used as a material for piezoelectric films having favorable heat resistance and favorable piezoelectric properties.

In the copolymer of the present embodiment, the array order of the structural unit including a triazole skeleton and the structural unit represented by Formula (2), which are repeating units, is not particularly limited. In addition, in the copolymer of the present embodiment, the number of the structural units including a triazole skeleton and the number of the structural units represented by Formula (2) may be the same as or different from each other. Therefore, in the copolymer of the present embodiment, an alternative array portion in which the structural units including a triazole skeleton and the structural units represented by Formula (2) are alternatively arrayed, a random array portion in which the structural units including a triazole skeleton and the structural units represented by Formula (2) are randomly arrayed, and a block array portion having a portion in which the structural units including a triazole skeleton are continuously arrayed and a portion in which the structural units represented by Formula (2) are continuously arrayed may be distributed in arbitrary proportions. The copolymer of the present embodiment preferably includes the alternative array portion since nitrile groups that are contained in the structural unit represented by Formula (2) are less likely to be oriented such that the polarities cancel out each other, and the copolymer can be used as a piezoelectric material having favorable heat resistance and favorable piezoelectric properties.

In the copolymer of the present embodiment, the amount of the structural unit including a triazole skeleton is preferably 20 to 80 mol %, more preferably 20 to 70 mol %, and still more preferably 30 to 70 mol %. When the amount of the structural unit including a triazole skeleton is 20 mol % or more, the copolymer becomes more favorable in terms of heat resistance. In addition, when the amount of the structural unit including a triazole skeleton is 80 mol % or less, it is possible to prevent piezoelectric films containing the copolymer from becoming hard and brittle due to the amount of the structural unit including a triazole skeleton being too large. In addition, when the amount of the structural unit including a triazole skeleton is 80 mol % or less, it is possible to suppress the insulation resistance of the copolymer being decreased due to the structural unit including a triazole skeleton absorbing moisture.

In the copolymer of the present embodiment, the amount of the structural unit represented by Formula (2) is preferably 20 to 80 mol %, more preferably 30 to 80 mol %, and still more preferably 30 to 70 mol %. When the amount of the structural unit represented by Formula (2) is 20 mol % or more, the copolymer enables flexible piezoelectric films having high insulation resistance to be formed. In addition, when the amount of the structural unit represented by Formula (2) is 80 mol % or less, it becomes easy to secure the amount of the structural unit including a triazole skeleton. As a result, the nitrile groups that are contained in the structural unit represented by Formula (2) are less likely to be oriented such that the polarities cancel out each other, and the copolymer enables piezoelectric films having more favorable heat resistance and more favorable piezoelectric properties to be formed.

The copolymer of the present embodiment may include one or more different structural units other than the structural unit including a triazole skeleton and the structural unit represented by Formula (2) as necessary. Examples of the different structural units include structural units derived from a well-known monomer or oligomer having a polymerizable unsaturated bond.

The total amount of the structural unit including a triazole skeleton and the structural unit represented by Formula (2) among the structural units that are contained in the copolymer of the present embodiment is preferably 50 mass % or more and more preferably 80 mass % or more. The total content may be 90 mass % or more, and only the structural unit including a triazole skeleton and the structural unit represented by Formula (2) may be included.

The weight-average molecular weight (Mw) of the copolymer of the present embodiment is preferably 10,000 to 1,000,000. When the weight-average molecular weight (Mw) of the copolymer is 10,000 or higher, the copolymer becomes favorable in terms of a film-forming property, and a piezoelectric film containing the copolymer of the present embodiment can be easily produced. When the weight-average molecular weight (Mw) of the copolymer is 1,000,000 or lower, it is possible to easily dissolve the copolymer in a solvent and to easily produce a piezoelectric film using a coating liquid containing the copolymer dissolved in a solvent.

### “Method for Producing Copolymer”

The copolymer of the present embodiment can be produced by, for example, a method in which radical copolymerization is performed by a well-known method using a compound from which the structural unit including a triazole skeleton is derived, a raw material monomer containing acrylonitrile, and a polymerization initiator, such as azobisisobutyronitrile.

Polymerization conditions, such as the reaction temperature and the reaction time, at the time of producing the copolymer of the present embodiment can be determined as appropriate depending on the composition of the raw material monomer or the like.

The compound from which the structural unit including a triazole skeleton is derived is a compound having a vinyl group bonded to a nitrogen atom in a triazole skeleton, in which the triazole skeleton and an atom that is bonded to a carbon atom in the triazole skeleton are the same as those in the structural unit including a triazole skeleton.

Examples of the compound from which the structural unit represented by Formula (1-3) is derived include 1-vinyl-1H-1,2,3-triazole, 1-vinyl-1H-1,2,3-triazole-4-methyl, 1-vinyl-1H-1,2,3-triazole-4-ethyl, 1-vinyl-1H-1,2,3-triazole-4-phenyl, 1-vinyl-1H-1,2,3-triazole-4-benzyl, 1-vinyl-1H-1,2,3-triazole-4-carbonitrile, 1-vinyl-1H-1,2,3-triazole-4-trifluoromethyl, and the like.

Examples of the compound from which the structural unit represented by Formula (1-2) is derived include 1-vinyl-1H-1,2,4-triazole, 1-vinyl-1H-1,2,4-triazole-3-carbonitrile, 1-vinyl-1H-1,2,4-triazole-3-trifluoromethyl, and the like.

Examples of the compound from which the structural unit represented by Formula (1-3) is derived include 4-vinyl-4H-1,2,4-triazole and the like. The compound can be determined as appropriate depending on the structure of the copolymer of the present embodiment, which is an intended object.

### “Piezoelectric Material”

A piezoelectric material of the present embodiment contains the copolymer of the present embodiment. Only one kind of the copolymer of the present embodiment or two or more kinds thereof may be contained in the piezoelectric material of the present embodiment. In addition, the piezoelectric material of the present embodiment may contain one or more kinds of well-known polymers other than the copolymer of the present embodiment together with the copolymer of the present embodiment as necessary.

### “Piezoelectric Film”

A piezoelectric film of the present embodiment contains the copolymer of the present embodiment.

The piezoelectric film of the present embodiment can be produced by, for example, a method to be described below. A coating liquid is produced by dissolving the piezoelectric material of the present embodiment containing the copolymer of the present embodiment in a solvent. As the solvent, a well-known solvent, such as N,N-dimethylformamide, can be used. Next, the coating liquid is applied onto a releasable substrate in a predetermined thickness to form a coated film. As the substrate, a well-known substrate, such as a resin film, can be used. As a method for applying the coating liquid, a well-known method can be used depending on the coating thickness, the viscosity of the coating liquid, or the like. After that, the coated film is dried, the solvent in the coated film is removed, and a piezoelectric material sheet is produced. A stretching process may be performed on the piezoelectric material sheet as necessary.

After that, the piezoelectric material sheet is released from the substrate, an electrode made of a well-known conductive material, such as aluminum, is installed on each of a first surface and a second surface of the piezoelectric material sheet. In addition, a voltage is applied to the piezoelectric material sheet at a temperature near the glass transition temperature of the piezoelectric material that forms the piezoelectric material sheet through the electrodes installed on both surfaces. After that, the piezoelectric material sheet is cooled while the voltage is being applied thereto.

Piezoelectricity is thus acquired. A sheet-like piezoelectric film is obtained by the above-described steps.

The electrodes used to acquire piezoelectricity may be used as they are as members for forming a piezoelectric element or may be removed.

### “Piezoelectric Element”

A piezoelectric element of the present embodiment has the piezoelectric film of the present embodiment and an electrode disposed on each of a first surface and a second surface of the piezoelectric film. A specific example thereof is a piezoelectric element having a sheet-like piezoelectric film and electrodes disposed on a first surface and a second surface of the piezoelectric film, respectively. As a material of the electrode, a well-known conductive material, such as aluminum, can be used.

The piezoelectric element of the present embodiment can be produced by, for example, providing an electrode on each of a first surface and a second surface of the piezoelectric film by a well-known method, such as a vapor deposition method.

The copolymer of the present embodiment has the structural unit including a triazole skeleton and the structural unit represented by Formula (2). Therefore, the copolymer of the present embodiment can be used as a piezoelectric material from which a piezoelectric film having high heat resistance and high piezoelectric properties can be obtained.

In addition, the piezoelectric material of the present embodiment contains the copolymer of the present embodiment and thus enables a piezoelectric film having high heat resistance and high piezoelectric properties to be obtained.

In addition, the piezoelectric film of the present embodiment contains the copolymer of the present embodiment. Therefore, the piezoelectric film of the present embodiment and the piezoelectric element of the present embodiment having the piezoelectric film of the present embodiment are excellent in terms of heat resistance and piezoelectric properties.

Hitherto, the embodiment of the present invention has been described in detail, but each configuration, a combination thereof, and the like in each embodiment are simply examples, and the addition, omission, substitution, and other modifications of the configuration are possible within the scope of the gist of the present invention.

### EXAMPLES

### Example 1

0.4 g (4 mmol) of 1-vinyl-1H-1,2,3-triazole represented by following General Formula (11) and 1 ml (16 mmol) of acrylonitrile were mixed together in a 100 ml Schlenk flask, and 10 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 0.9 g of a polymer of Example 1. The yield was 72%.

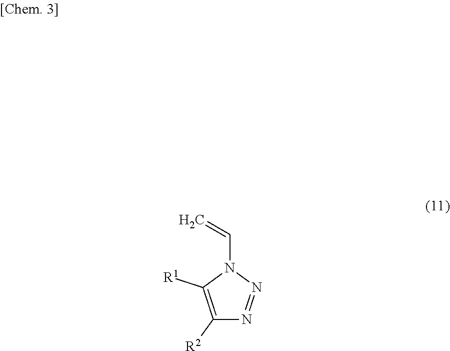

(In General Formula (11), R¹ and R² are hydrogen atoms.)

On the polymer of Example 1, 1H-NMR measurement was performed using an NMR (nuclear magnetic resonance) device (trade name JNM-ECA500, manufactured by JEOL Ltd.) and dimethyl sulfoxide d6 (DMSO-d6) as a solvent, thereby specifying the molecular structure.

As a result, it was possible to confirm that the polymer of Example 1 was a copolymer having a structural unit represented by General Formula (1-1) (R¹ and R² in General Formula (1-1) were hydrogen atoms) and a structural unit represented by Formula (2).

In addition, a composition ratio was calculated from the integral value of individual signals in the 1H-NMR spectrum of Example 1. As a result, the amount of the structural unit represented by Formula (2) that was included in the polymer of Example 1 was 83 mol %.

### Example 2

1.0 g (10 mmol) of 1-vinyl-1H-1,2,3-triazole and 1.0 ml (16 mmol) of acrylonitrile were mixed together in a 100 ml Schlenk flask, and 18.7 mg (0.11 mmol) of azobisisobutyronitrile was added thereto, and the components were reacted at 60° C. for two hours. A reaction product was injected into 200 ml of methanol, reprecipitated, filtered, and dried, thereby obtaining 1.5 g of a polymer of Example 2. The yield was 84%.

On the polymer of Example 2, 1H-NMR measurement was performed in the same manner as for the polymer of Example 1, thereby specifying the molecular structure. As a result, it was possible to confirm that the polymer of Example 2 was, similar to the polymer of Example 1, a copolymer having a structural unit represented by General Formula (1-1) (R¹ and R² in General Formula (1-1) were hydrogen atoms) and a structural unit represented by Formula (2).

In addition, a composition ratio was calculated from the integral value of individual signals in the 1H-NMR spectrum of Example 2. As a result, the amount of the structural unit represented by Formula (2) that was included in the polymer of Example 2 was 66 mol %.

### Example 3

0.8 g (8 mmol) of 1-vinyl-1H-1,2,3-triazole and 0.5 ml (8 mmol) of acrylonitrile were mixed together in a 100 ml Schlenk flask, and 9.5 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 0.8 g of a polymer of Example 3. The yield was 77%.

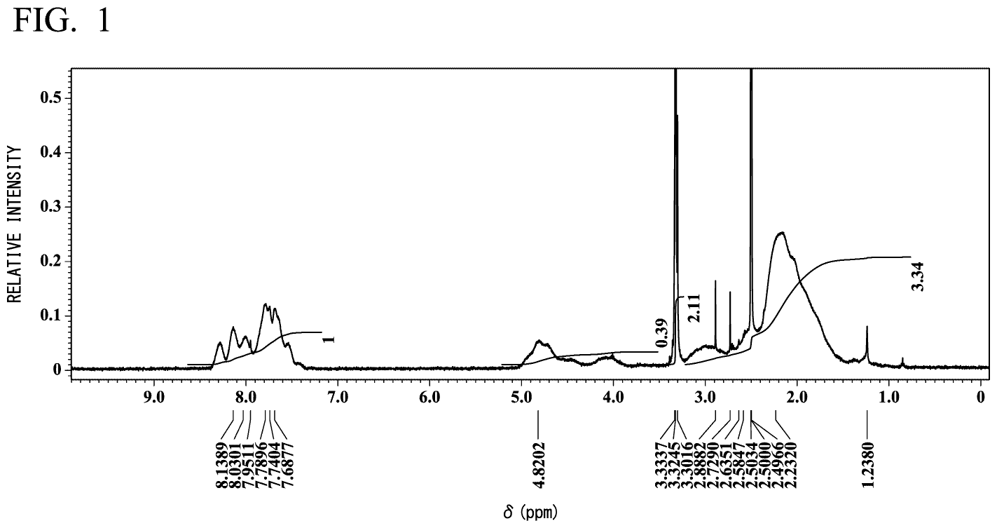

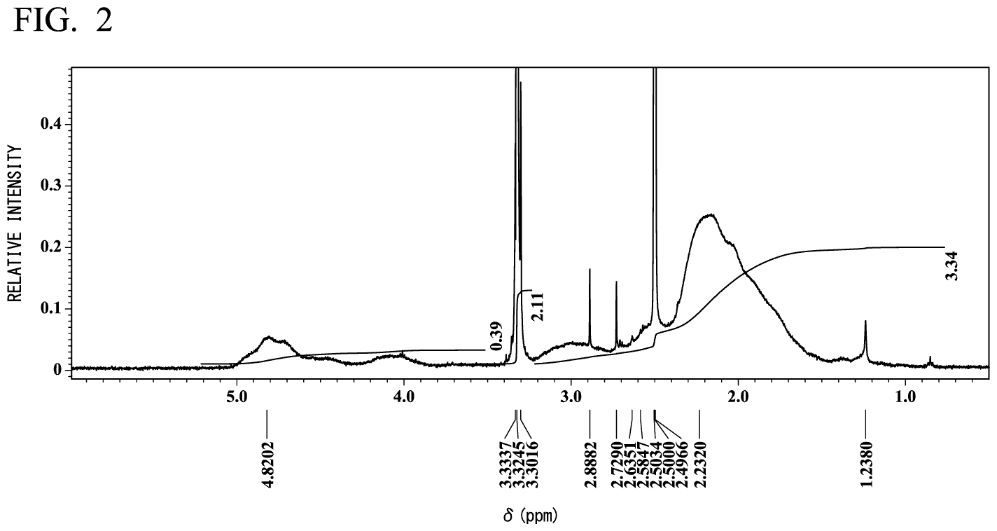

On the polymer of Example 3, 1H-NMR measurement was performed in the same manner as for the polymer of Example 1. FIG. 1 is a 1H-NMR measurement chart of the polymer of Example 3. FIG. 2 is an enlarged view obtained by enlarging a part of FIG. 1. In addition, regarding the polymer of Example 3, the molecular structure was specified using the result of the 1H-NMR measurement. As a result, it was possible to confirm that the polymer of Example 3 was, similar to the polymer of Example 1, a copolymer having a structural unit represented by General Formula (1-1) (R¹ and R² in General Formula (1-1) were hydrogen atoms) and a structural unit represented by Formula (2).

In addition, a composition ratio was calculated from the integral value of individual signals in the 1H-NMR spectrum of Example 3. As a result, the amount of the structural unit represented by Formula (2) that was included in the polymer of Example 3 was 50 mol %.

### Example 4

0.8 g (8 mmol) of 1-vinyl-1H-1,2,3-triazole and 0.3 ml (4 mmol) of acrylonitrile were mixed together in a 100 ml Schlenk flask, and 7.8 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 4. The yield was 66%.

On the polymer of Example 4, ¹H-NMR measurement was performed in the same manner as for the polymer of Example 1, thereby specifying the molecular structure. As a result, it was possible to confirm that the polymer of Example 4 was, similar to the polymer of Example 1, a copolymer having a structural unit represented by General Formula (1-1) (R¹ and R² in General Formula (1-1) were hydrogen atoms) and a structural unit represented by Formula (2).

In addition, a composition ratio was calculated from the integral value of individual signals in the 1H-NMR spectrum of Example 4. As a result, the amount of the structural unit represented by Formula (2) that was included in the polymer of Example 4 was 37 mol %.

### Example 5

0.8 g (8 mmol) of 1-vinyl-1H-1,2,3-triazole and 0.1 ml (2 mmol) of acrylonitrile were mixed together in a 100 ml Schlenk flask, and 6.9 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.5 g of a polymer of Example 5. The yield was 58%.

On the polymer of Example 5, 1H-NMR measurement was performed in the same manner as for the polymer of Example 1, thereby specifying the molecular structure. As a result, it was possible to confirm that the polymer of Example 5 was, similar to the polymer of Example 1, a copolymer having a structural unit represented by General Formula (1-1) (R¹ and R² in General Formula (1-1) were hydrogen atoms) and a structural unit represented by Formula (2).

In addition, a composition ratio was calculated from the integral value of individual signals in the 1H-NMR spectrum of Example 5. As a result, the amount of the structural unit represented by Formula (2) that was included in the polymer of Example 5 was 19 mol %.

### Example 6

0.2 g (2 mmol) of 1-vinyl-1H-1,2,4-triazole represented by following General Formula (12) and 0.5 ml (8 mmol) of acrylonitrile were mixed together in a 100 ml Schlenk flask, and 4.9 mg (0.03 mmol) of azobisisobutyronitrile was added thereto, and the components were reacted at 60° C. for two hours. A reaction product was injected into 200 ml of methanol, reprecipitated, filtered, and dried, thereby obtaining 0.5 g of a polymer of Example 6. The yield was 87%.

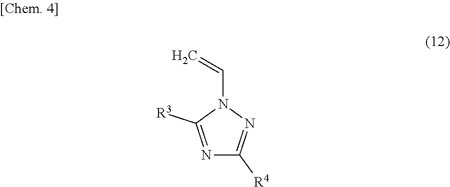

(In General Formula (12), R³ and R⁴ are hydrogen atoms.)

On the polymer of Example 6, 1H-NMR measurement was performed in the same manner as for the polymer of Example 1, thereby specifying the molecular structure. As a result, it was possible to confirm that the polymer of Example 6 was a copolymer having a structural unit represented by General Formula (1-2) (R³ and R⁴ in General Formula (1-2) were hydrogen atoms) and a structural unit represented by Formula (2).

In addition, a composition ratio was calculated from the integral value of individual signals in the 1H-NMR spectrum of Example 6. As a result, the amount of the structural unit represented by Formula (2) that was included in the polymer of Example 6 was 80 mol %.

### Example 7

0.5 g (5 mmol) of 1-vinyl-1H-1,2,4-triazole and 0.5 ml (8 mmol) of acrylonitrile were mixed together in a 100 ml Schlenk flask, and 7.2 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Example 7. The yield was 75%.

On the polymer of Example 7, 1H-NMR measurement was performed in the same manner as for the polymer of Example 1, thereby specifying the molecular structure. As a result, it was possible to confirm that the polymer of Example 7 was a copolymer having a structural unit represented by General Formula (1-2) (R³ and R⁴ in General Formula (1-2) were hydrogen atoms) and a structural unit represented by Formula (2).

In addition, a composition ratio was calculated from the integral value of individual signals in the 1H-NMR spectrum of Example 7. As a result, the amount of the structural unit represented by Formula (2) that was included in the polymer of Example 7 was 61 mol %.

### Example 8

0.8 g (8 mmol) of 1-vinyl-1H-1,2,4-triazole and 0.5 ml (8 mmol) of acrylonitrile were mixed together in a 100 ml Schlenk flask, and 9.4 mg (0.06 mmol) of azobisisobutyronitrile was added thereto, and the components were reacted at 60° C. for two hours. A reaction product was injected into 200 ml of methanol, reprecipitated, filtered, and dried, thereby obtaining 0.8 g of a polymer of Example 8. The yield was 68%.

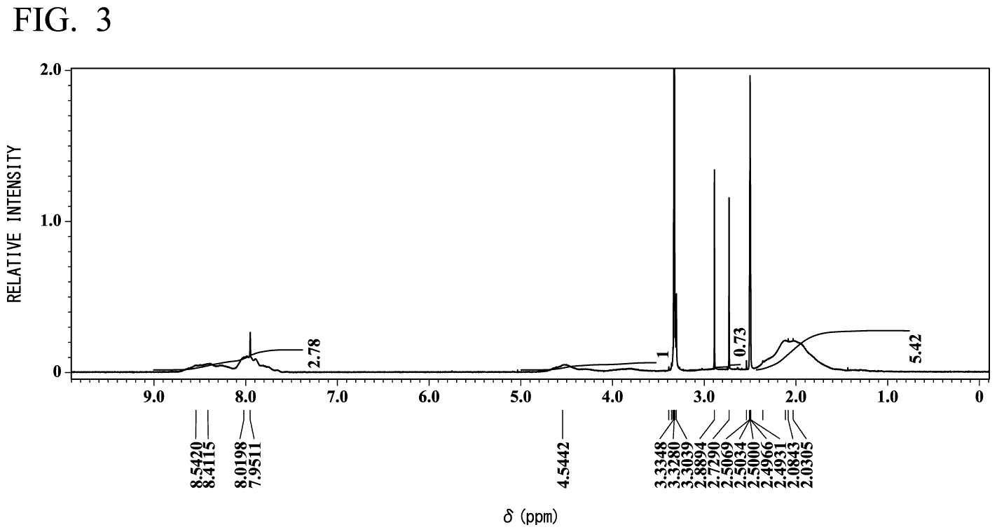

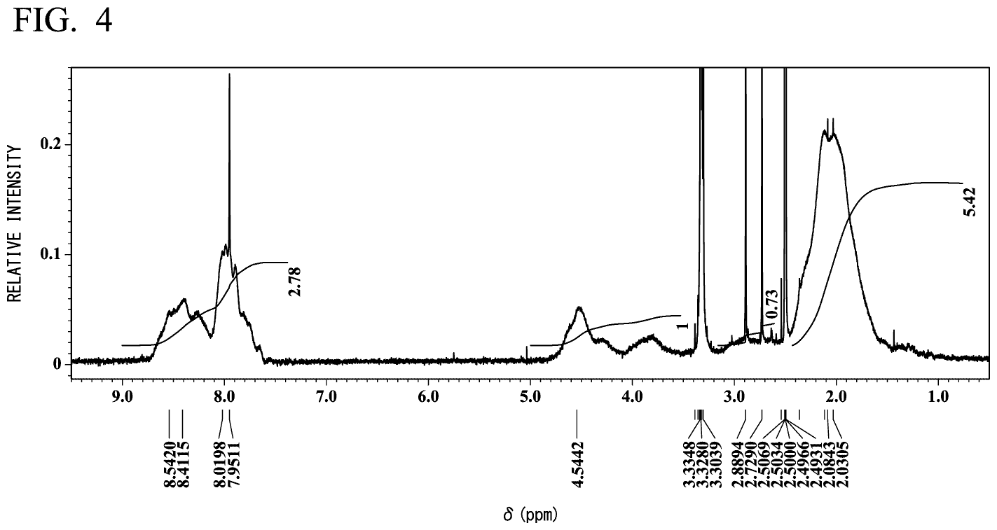

On the polymer of Example 8, 1H-NMR measurement was performed in the same manner as for the polymer of Example 1, thereby specifying the molecular structure. FIG. 3 is a ¹H-NMR measurement chart of the polymer of Example 8. FIG. 4 is an enlarged view obtained by enlarging a part of FIG. 3. In addition, regarding the polymer of Example 8, the molecular structure was specified using the result of the 1H-NMR measurement. As a result, it was possible to confirm that the polymer of Example 8 was, similar to the polymer of Example 6, a copolymer having a structural unit represented by General Formula (1-2) (R³ and R⁴ in General Formula (1-2) were hydrogen atoms) and a structural unit represented by Formula (2).

In addition, a composition ratio was calculated from the integral value of individual signals in the 1H-NMR spectrum of Example 8. As a result, the amount of the structural unit represented by Formula (2) that was included in the polymer of Example 8 was 50 mol %.

### Example 9

0.8 g (8 mmol) of 1-vinyl-1H-1,2,4-triazole and 0.3 ml (4 mmol) of acrylonitrile were mixed together in a 100 ml Schlenk flask, and 7.8 mg (0.05 mmol) of azobisisobutyronitrile was added thereto, and the components were reacted at 60° C. for two hours. A reaction product was injected into 200 ml of methanol, reprecipitated, filtered, and dried, thereby obtaining 0.7 g of a polymer of Example 9. The yield was 75%.

On the polymer of Example 9, 1H-NMR measurement was performed in the same manner as for the polymer of Example 1, thereby specifying the molecular structure. As a result, it was possible to confirm that the polymer of Example 9 was, similar to the polymer of Example 6, a copolymer having a structural unit represented by General Formula (1-2) (R¹ and R² in General Formula (1-2) were hydrogen elements) and a structural unit represented by Formula (2).

In addition, a composition ratio was calculated from the integral value of individual signals in the 1H-NMR spectrum of Example 9. As a result, the amount of the structural unit represented by Formula (2) that was included in the polymer of Example 9 was 33 mol %.

### Example 10

0.8 g (8 mmol) of 1-vinyl-1H-1,2,4-triazole and 0.1 ml (2 mmol) of acrylonitrile were mixed together in a 100 ml Schlenk flask, and 6.9 mg (0.04 mmol) of azobisisobutyronitrile was added thereto, and the components were reacted at 60° C. for two hours. A reaction product was injected into 200 ml of methanol, reprecipitated, filtered, and dried, thereby obtaining 0.6 g of a polymer of Example 10. The yield was 69%.

On the polymer of Example 10, 1H-NMR measurement was performed in the same manner as for the polymer of Example 1. As a result, it was possible to confirm that the polymer of Example 10 was, similar to the polymer of Example 6, a copolymer having a structural unit represented by General Formula (1-2) (R³ and R⁴ in General Formula (1-2) were hydrogen atoms) and a structural unit represented by Formula (2).

In addition, a composition ratio was calculated from the integral value of individual signals in the 1H-NMR spectrum of Example 10. As a result, the amount of the structural unit represented by Formula (2) that was included in the polymer of Example 10 was 17 mol %.

### Comparative Example 1

Polyacrylonitrile (trade name 181315, manufactured by Sigma-Aldrich) was used as a polymer of Comparative Example 1.

### Comparative Example 2

Poly(acrylonitrile-CO-methyl acrylate) (trade name 517941, manufactured by Sigma-Aldrich) was used as a polymer of Comparative Example 2.

For each of the polymers of Example 1 to Example 10 obtained as described above, R¹ to R⁴ in the structural unit represented by General Formula (1-1) or General Formula (1-2) and the amount of the structural unit represented by Formula (2) are shown in Table 1.

In addition, the names of the compounds for the polymers of Comparative Example 1 and Comparative Example 2 and the contents of the structural units represented by Formula (2) in the polymers are each shown in Table 1.

TABLE 1

| | | Amount of | Glass | |
|---|---|---|---|---|
| | | structural | tran- | |
| | | unit | sition | |
| | | represented | temper- | d₃₃ |
| | Structural unit or | by Formula (2) | ature | (pC/ |
| | polymer name | (mol %) | (° C.) | N) |
| Example 1 | Formula (1-1), R^{1, 2} = H | 83 | 125 | 2.2 |
| Example 2 | Formula (1-1), R^{1, 2} = H | 66 | 134 | 4.3 |
| Example 3 | Formula (1-1), R^{1, 2} = H | 50 | 151 | 4.5 |
| Example 4 | Formula (1-1), R^{1, 2} = H | 37 | 165 | 4.0 |
| Example 5 | Formula (1-1), R^{1 2} = H | 19 | 174 | 2.3 |
| Example 6 | Formula (1-2), R^{3, 4} = H | 80 | 123 | 2.5 |
| Example 7 | Formula (1-2), R^{3, 4} = H | 61 | 137 | 2.9 |
| Example 8 | Formula (1-2), R^{3, 4} = H | 50 | 145 | 3.6 |
| Example 9 | Formula (1-2), R^{3, 4} = H | 33 | 161 | 3.1 |
| Example 10 | Formula (1-2), R^{3, 4} = H | 17 | 166 | 2.3 |
| Comparative | Polyacrylonitrile | 100 | 98 | 0.8 |
| Example 1 | | | | |
| Comparative | Poly(acrylonitrile-co- | 96 | 97 | 0.7 |
| Example 2 | methyl acrylate) | | | |

For each of the polymers of Example 1 to Example 10, Comparative Example 1, and Comparative Example 2, the glass transition temperature (Tg) was measured by a method to be described below. The results are shown in Table 1.

### (Method for Measuring Glass Transition Temperature (Tg))

A heating and cooling operation of heating the polymer from 30° C. to 200° C. at a heating rate of 20° C./minute, cooling the polymer from 200° C. to 30° C. at a cooling rate of 40° C./minute, and heating the polymer from 30° C. to 200° C. at a heating rate of 20° C./minute in a nitrogen atmosphere was performed using a high-sensitivity differential scanning calorimeter (trade name, DSC6200, manufactured by Seiko Instruments Inc.), and the inflection point at the time of the second heating was obtained and regarded as the glass transition temperature (Tg).

In addition, a piezoelectric film was produced by a method to be described below using each of the polymers of Example 1 to Example 10, Comparative Example 1, and Comparative Example 2 as a piezoelectric material, and the piezoelectric constant d₃₃ was measured. The results are shown in Table 1.

### (Production of Piezoelectric Film)

The piezoelectric material was dissolved in N,N-dimethylformamide, which was a solvent, to produce 20 mass % of a polymer solution (coating liquid). The obtained polymer solution was applied onto a PET film (trade name, LUMIRROR (registered trademark), manufactured by Toray Industries, Inc.), which was a substrate, such that the dried thickness reached 50 μm to form a coated film. After that, the coated film formed on the PET film was dried at 120° C. for six hours on a hot plate to remove the solvent in the coated film, thereby obtaining a piezoelectric material sheet.

The obtained piezoelectric material sheet was released from the PET film, and an electrode made of aluminum was provided on each of a first surface and a second surface of the piezoelectric material sheet by a vapor deposition method. After that, a high voltage power supply HARB-20R⁶⁰ (manufactured by Matsusada Precision Inc.) and the electrodes of the piezoelectric material sheet were electrically connected together and held at 140° C. for 15 minutes in a state where an electric field of 100 MV/m was applied thereto. After that, the piezoelectric material sheet was slowly cooled to room temperature under the application of the voltage, and a polling process was performed thereon, thereby obtaining a sheet-like piezoelectric film.

(Method for Measuring Piezoelectric Constant d₃₃)

The piezoelectric film was mounted in a measuring instrument using a pin having a diameter of 1.5 mm at the front end as a sample-fixing jig. As the measuring instrument of the piezoelectric constant d₃₃, a PiezoMeter System PM200 manufactured by Piezotest Pte Ltd. was used.

The actual measurement value of the piezoelectric constant d₃₃ becomes a positive value or a negative value depending on whether the surface of the piezoelectric film that is measured is a front surface or a rear surface. In the present specification, the absolute value of the actual measurement value was used as the value of the piezoelectric constant d₃₃.

As shown in Table 1, it was possible to confirm that the polymers of Example 1 to Example 10 had high glass transition temperatures (Tg) and favorable heat resistance compared with the polymers of Comparative Example 1 and Comparative Example 2. In addition, the piezoelectric films of Example 1 to Example 10 containing the polymers of Example 1 to Example 10 had high piezoelectric constants d₃₃ and favorable piezoelectric properties compared with the piezoelectric film of Comparative Example 1 containing the polymer of Comparative Example 1 and the piezoelectric film of Comparative Example 2 containing the polymer of Comparative Example 2.

Particularly, the piezoelectric films containing the polymers of Example 2 to Example 4 and Example 6 to Example 9 in which the amount of the structural unit represented by Formula (2) was 20 to 80 mol % had high piezoelectric constants d₃₃ and favorable piezoelectric properties.

### INDUSTRIAL APPLICABILITY

The copolymer of the present invention can be used as a piezoelectric material from which a piezoelectric film having high heat resistance and high piezoelectric properties can be obtained.

1. A copolymer comprising:
a structural unit including a triazole skeleton; and
a structural unit represented by following Formula (2),
wherein the structural unit including a triazole skeleton is any one or more of following General Formula (1-1) to General Formula (1-3), 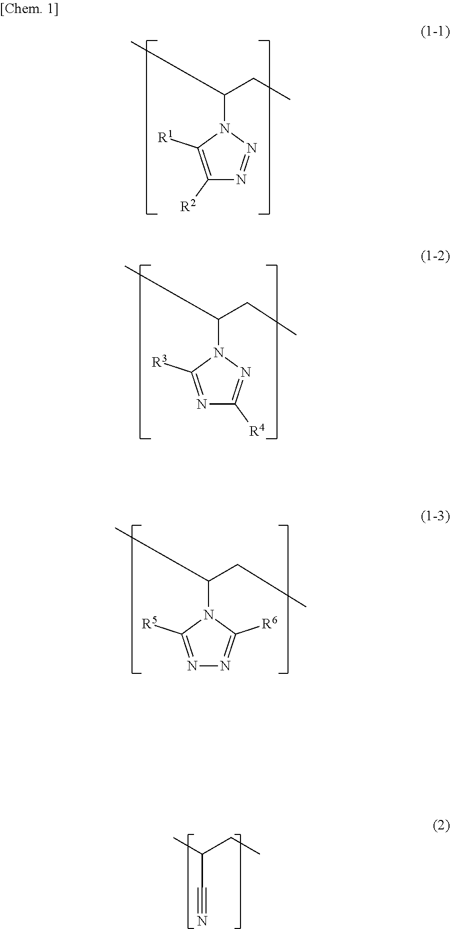
(in the General Formula (1-1) to the General Formula (1-3), R¹ to R⁶ are each any one selected from the group consisting of a hydrogen atom, a methyl group, a trifluoromethyl group, a nitrile group, a fluorine atom, a methoxy group, an ethyl group, an ethoxy group, a methoxymethyl group, a propyl group, an isopropyl group, a cyclopropyl group, a butyl group, an isobutyl group, a (trimethyl)methyl group, a (trimethyl) silyl group, a pentyl group, an isopentyl group, a t-pentyl group, a neopentyl group, a cyclopentyl group, a hexyl group, a cyclohexyl group, a phenyl group, a tolyl group, a benzyl group, and a phenoxymethyl group, or R¹ to R⁶ each form a benzotriazole skeleton together with a triazole ring).

2. The copolymer according to claim 1,
wherein, in the General Formula (1-1) to the General Formula (1-3), R¹ to R⁶ are hydrogen atoms.

3. The copolymer according to claim 1,
wherein an amount of the structural unit represented by the Formula (2) is 20 to 80 mol %.

4. A piezoelectric material comprising:
the copolymer according to claim 1.

5. A piezoelectric film comprising:
the copolymer according to claim 1.

6. A piezoelectric element comprising:
the piezoelectric film according to claim 5; and
an electrode disposed on each of a first surface and a second surface of the piezoelectric film.
